(19) United States
(12) Patent Application Publication
(10) Pub. No.: US 2008/0136465 A1
(43) Pub. Date: Jun. 12, 2008

(54) SEMICONDUCTOR INTEGRATED CIRCUIT

(75) Inventor: Shingo Takagi, Kawasaki-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/951,845

(22) Filed: Dec. 6, 2007

(30) Foreign Application Priority Data
Dec. 8, 2006 (JP) 2006-332152

(51) Int. Cl. H03B 1/00

(52) U.S. Cl. 327/108

(57) ABSTRACT

A semiconductor integrated circuit is disclosed, which includes a current output buffer circuit including a differential circuit, a variable impedance circuit, and a constant current source, wherein the current output buffer circuit is driven by a constant current supplied by the constant current source, an output impedance of the current output buffer circuit is controlled in accordance with a bit rate of differential transmission signal inputs inputted to the differential circuit so that a waveform of a signal output from the current output buffer circuit to a signal transmission line is controlled in accordance with the bit rate of the transmission signal inputs.

### CROSS-REFERENCE TO RELATED APPLICATIONS

This application is based upon and claims the benefit of priority from prior Japanese Patent Application No. 2006-332152, filed Dec. 8, 2006, the entire contents of which are incorporated herein by reference.

### BACKGROUND OF THE INVENTION

1. Field of the Invention

The present invention relates to a semiconductor integrated circuit, and more particularly, to an output buffer circuit, and is used to compensate for transmission loss in high-speed signal transmission on a signal transmission line to realize a high-quality signal waveform.

2. Description of the Related Art

When high-speed signal transmission is performed between, for example, a personal computer and an external storage device, or between a television receiver set and a DVD recording/reproduction device by using a wire, if a bit rate is high, a sufficient signal amplitude cannot be assured due to a loss of a high-frequency component on the signal transmission line. For this reason, as a technique for compensating for amplitude loss on a signal transmission line, emphasis is used. In the general emphasis, emphasis is realized by increasing a current flowing through an output buffer circuit only when a bit rate of a transmission signal is high or when a transmission signal rises or falls (Jpn. Pat. Appln. KOKAI Publication No. 2002-368600). However, normally, the current for driving the output buffer circuit is very large, and hence the current to be increased for the purpose of realizing emphasis becomes very large, thereby causing a great increase in the current consumption of the entire system.

### BRIEF SUMMARY OF THE INVENTION

According to a first aspect of the present invention, there is provided a semiconductor integrated circuit comprising:

a current output buffer circuit including a differential circuit, a variable impedance circuit, and a constant current source, wherein

the current output buffer circuit is driven by a constant current supplied by the constant current source, an output impedance of the current output buffer circuit is controlled in accordance with a bit rate of differential transmission signal inputs inputted to the differential circuit so that a waveform of a signal output from the current output buffer circuit to a signal transmission line is controlled in accordance with the bit rate of the transmission signal inputs.

According to a second aspect of the present invention, there is provided a semiconductor integrated circuit comprising:

an input terminal which receives a transmission signal input;

an output terminal; and

a current output buffer circuit connected between the input terminal and the output terminal and driven by a constant current source, in which

an output impedance of the current output buffer circuit is controlled in accordance with a bit rate of a transmission signal input inputted to the input terminal so that a waveform of a signal output from the current output buffer circuit to a signal transmission line is controlled in accordance with the bit rate of the transmission signal input.

According to a third aspect of the present invention, there is provided a current output buffer circuit comprising:

a differential circuit which includes a pair of differential transistors,

an impedance circuit which includes a pair of variable resistance circuits connected in series to the pair of differential transistors, respectively, and

a constant current source which is connected between a node of the pair of differential transistors and the pair of variable resistance circuits and a reference potential terminal and supplies a constant current flowing through the pair of variable resistance circuits and the pair of differential transistors.

### BRIEF DESCRIPTION OF THE SEVERAL VIEWS OF THE DRAWING

FIG. 1 is a circuit diagram showing an output buffer circuit of a CML (Current Mirror Logic) type according to a first embodiment of the present invention.

FIG. 2 is a timing waveform chart of an operation of the current output buffer circuit of FIG. 1, and shows a relationship between a bit rate of transmission signal inputs inp and inn, control signals inp_em and inn_em input to variable impedance circuits, amplitudes Vop and Von of the output signals, and a differential amplification of the amplitudes Vop and Von of the output signals.

FIG. 3 is a circuit diagram showing an output buffer circuit of a CML type according to a second embodiment of the present invention.

### DETAILED DESCRIPTION OF THE INVENTION

Embodiments of the present invention will be described below with reference to the accompanying drawings. In the description, parts common to all the drawings are denoted by common reference symbols.

### First Embodiment

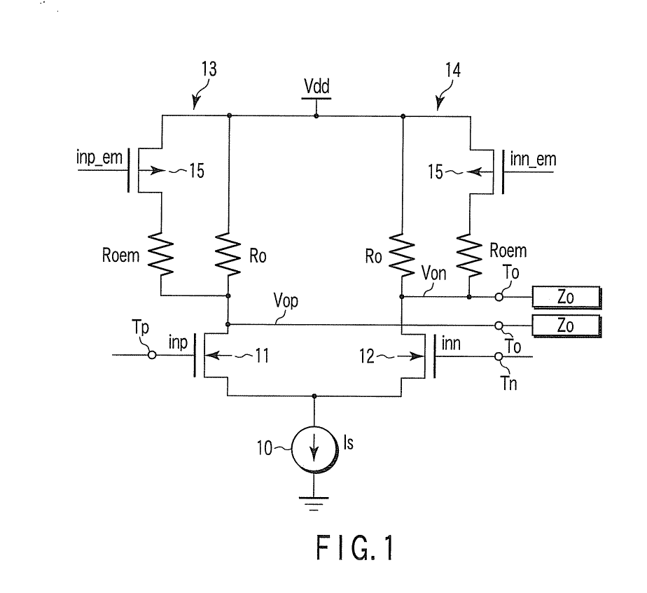

FIG. 1 is a circuit diagram showing a CML (Current Mirror Logic) type output buffer circuit in a semiconductor circuit according to a first embodiment of the present invention. In FIG. 1, reference symbols 11 and 12 denote NMOS transistors for a differential input to which differential transmission signal inputs inp and inn are input through signal input terminals Tp and Tn, respectively. Sources of the transistors 11 and 12 are connected to each other. Reference symbols 13 and 14 denote variable impedance circuits. The variable impedance circuit 13 is interposed between a power source potential Vdd (a high-potential side power source potential) and a drain of the transistor 11. The variable impedance circuit 14 is interposed between the power source potential Vdd and a drain of the transistor 12. The drains of the transistors 11 and 12 are connected to signal transmission lines through signal output terminals To and To, respectively. Each of the signal transmission lines has an impedance Zo. A reference symbol 10 denotes a constant current source circuit interposed between a node of the sources of the transistors 11 and 12 and a ground potential Vss (a low potential side power source potential). The constant current source circuit 10 flows a constant current Is.

Each of the variable impedance circuits 13 and 14 includes two or more parallel resistance elements controlled by a control signal so that the combined resistance of the parallel resistance elements equals to the impedance Zo of each of the signal transmission lines. In this embodiment, the parallel resistance elements includes a selectively connected resistance element Roem and a fixedly connected resistance element Ro. Each of the variable impedance circuits 13 and 14 further includes a PMOS transistor 15 connected in series to the resistance element Roem. The PMOS transistor 15 of each of the variable impedance circuits 13 and 14 functions as a switch element. A control signal inp_em synchronized with the transmission signal inp is input to the gate of the PMOS transistor 15 of the variable impedance circuit 13. Similarly, a control signal inn_em synchronized with the transmission signal inn is input to the gate of the PMOS transistor 15 of the variable impedance circuit 14. The control signals inp_em and inn_em become temporarily active (a high level in this embodiment) when the transmission signal inputs inp and inn rise, respectively. Further, the control signals inp_em and inn_em are active during the entire active period of the transmission signal inputs inp and inn, respectively, when the bit rate of the transmission signal inputs inp and inn is high.

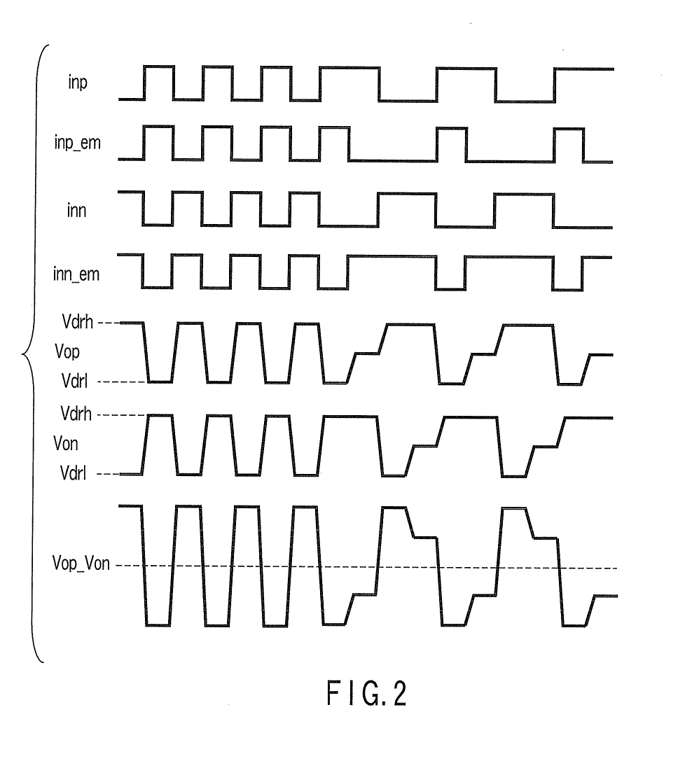

FIG. 2 is a timing waveform chart of an operation of the current output buffer circuit of FIG. 1, and shows a relationship between the bit rate of the transmission signal inputs inp and inn input to the buffer circuit, the control signals inp_em and inn_em input to the variable impedance circuits 13 and 14, respectively, amplitudes Vop and Von of the output signals (i.e., voltages on the drains of NMOS transistors 11 and 12, respectively) and a differential amplification of the amplitudes Vop and Von of the output signals. The transmission signal input inn and the control signal inn_em are inverted signals of the transmission signal input inp and the control signal inp_em, respectively. When the bit rate of the transmission signal inputs inp and inn is high, it is, for example, 1 GHz, on the other hand, when it is low, it is, for example, 500 MHz.

An example of an operation of the current output buffer circuit shown in FIG. 1 will be described below with reference to FIG. 2.

The current output buffer circuit is driven by a constant current Is supplied by the constant current source circuit 10, and the NMOS transistors 11 and 12 are differentially driven by the transmission signal inputs inp and inn, respectively.

In each of the variable impedance circuits 13 and 14, the combined resistance of the resistance elements Ro and Roem connected in parallel is given by the following formula (1).

Ro×Roem/(Ro+Roem)=Zo (1)

The resistance Roem is given by the following formula (2) obtained by modifying formula (1).

Roem=Ro×Zo/(Ro−Zo) (2)

When the high level of the output voltages of the drain nodes (output nodes) of the NMOS transistors 11 and 12 is denoted by Vdrh and the low level thereof is denoted by Vdrl, the amplitudes Vop and Von of the output signals are given by the following formula (3).

Vop=Von=Vdrh−Vdrl (3)

If the current Is is increased so as to lower the low level Vdrl in order to increase the amplitudes Vop and Von of the output signals, the current consumption becomes large. In light of this point, in this embodiment, in order to increase the output signal amplitudes Vop and Von, control is performed in such a manner that the resistance of the variable impedance circuit 13 or 14 is temporarily increased by the control signals inp_em and inn_em at a timing at which the low level Vdrl is lowered. More specifically, at the rising time of the transmission signal inputs inp and inn, or in the active period of the transmission signal inputs inp and inn when the bit rate of the transmission signal inputs inp and inn is high, the control signals inp_em and inn_em are active, and thus the PMOS transistor 15 of one of the variable impedance circuits 13 and 14 is controlled so as to be turned off, and the output impedance of the variable impedance circuit becomes high. On the other hand, the PMOS transistor 15 of the other of the variable impedance circuits 13 and 14 is controlled so as to be turned on, and the output impedance of the variable impedance circuit becomes low, that is, matches to Zo.

For example, at the rising time of the transmission signal input inp, the control signal inp_em is active. Thus, the PMOS transistor 15 of the variable impedance circuit 13 is controlled so as to be turned off, and the output impedance of the variable impedance circuit 13 becomes high, and on the other hand, the PMOS transistor 15 of the variable impedance circuit 14 is controlled so as to be turned on, and the output impedance of the variable impedance circuit 14 becomes low, that is, matches to Zo.

At the rising time of the transmission signal input inn, the control signal inn_em is active. Thus, the PMOS transistor 15 of the variable impedance circuit 14 is controlled so as to be turned off, and the output impedance of the variable impedance circuit 14 becomes high, and on the other hand, the PMOS transistor 15 of the variable impedance circuit 13 is controlled so as to be turned on, and the output impedance of the variable impedance circuit 13 becomes low, that is, matches to Zo.

In the active period of the transmission signal input inp when the bit rate of the transmission signal input inp is high, the control signal inp_em is active. Thus, the PMOS transistor 15 of the variable impedance circuit 13 is controlled so as to be turned off, and the output impedance of the variable impedance circuit 13 becomes high, and on the other hand, the PMOS transistor 15 of the variable impedance circuit 14 is controlled so as to be turned on, and the output impedance of the variable impedance circuit 14 becomes low, that is, matches to Zo.

In the active period of the transmission signal input inn when the bit rate of the transmission signal input inn is high, the control signal inn_em is active. Thus, the PMOS transistor 15 of the variable impedance circuit 14 is controlled so as to be turned off, and the output impedance of the variable impedance circuit 14 becomes high, and on the other hand, the PMOS transistor 15 of the variable impedance circuit 13 is controlled so as to be turned on, and the output impedance of the variable impedance circuit 13 becomes low, that is, matches to Zo.

As described above, at the rising time of the transmission signal inputs inp and inn, or in the active period of the transmission signal inputs inp and inn when the bit rate of the transmission signal inputs inp and inn is high, control is performed in such a manner that the output impedance becomes high. Hence, the differential amplitude (Vop−Von) between the signal amplitudes Vop and Von of the transmission signal inputs inp and inn is emphasized at the rising time of the transmission signal inputs inp and inn, and in the active period of the transmission signal inputs inp and inn when the bit rate of the transmission signal inputs inp and inn is high. As a result, the differential amplitude of the high-speed signal output to the signal transmission line is emphasized, and thus the attenuation in the high-speed signal transmission is compensated. When the bit rate of the transmission signal inputs inp and inn is low, control is performed in such a manner that the output impedance becomes low, so that the differential amplitude of the low-speed signal output to the signal transmission line is attenuated.

An example of an operation will be described below by using a formula. In each of the variable impedance circuits 13 and 14, the voltage of the output node of the variable impedance circuit obtained when the resistance elements Ro and Roem are connected in parallel to each other is the high level Vdrh of the output signal. On the other hand, in each of the variable impedance circuits 13 and 14, the voltage of the output node of the variable impedance circuit obtained when the resistance element Roem is separated from the circuit is the low level Vdrl of the output signal. The low level Vdrl is expressed by the following formula (4).

Vdrl=Vdd−Is×Ro (4)

Accordingly, by properly setting Ro to increase Is×Ro, it is possible to increase the amplitude Vop and Von of the output signals to a desired magnitude without increasing the current Is, i.e., without increasing the current consumption.

That is, according to the current output buffer circuit of the above embodiment, the output impedance thereof is normally the output impedance Ro×Roem/(Ro+Roem) matched to the impedance Zo of the transmission line and, on the other hand, when it is desired to increase the differential amplitude of the output signal, that is, when it is desired to emphasize the differential amplitude of the output signals, for example, at high bit rate of the transmission signal, or the rising time or falling time of the transmission signal, it is possible to increase the output impedance.

### Second Embodiment

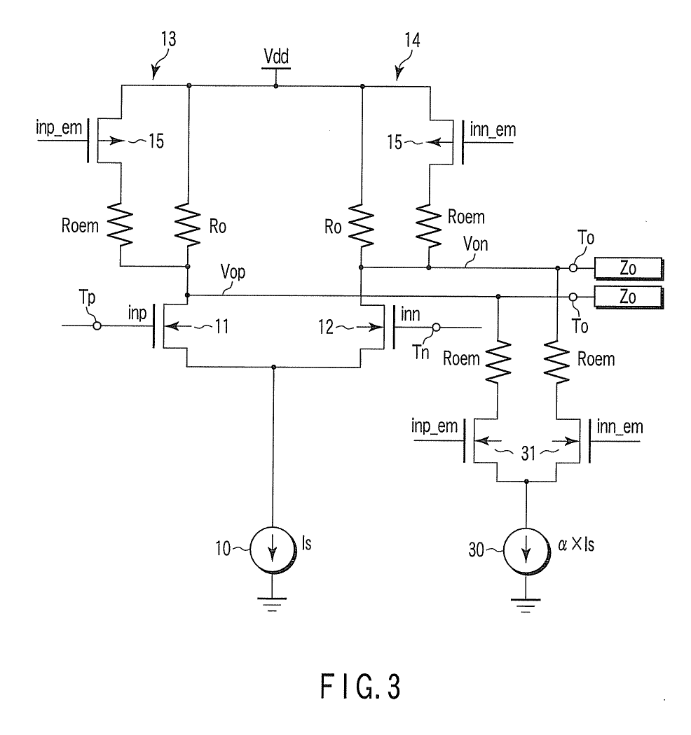

FIG. 3 is a circuit diagram showing an output buffer circuit of a CML type according to a second embodiment of the present invention. The second embodiment is basically identical with the first embodiment, except that a control resistance element Roem is connected in series to each of the variable impedance circuits 13 and 14, a current source 30 is interposed between the node of the resistance elements Roem and the ground node, and a NMOS transistors 31 functioning as a switch element is connected in series to each of the control resistance elements Roem between the node of the control resistance elements Roem and the current source 30. That is, a series connected circuit of the control resistance element Roem and the NMOS transistor 31 is interposed between one end of each of the variable impedance circuits 13 and 14 on the output node side and the current source 30. Complementary control signals inp_em and inn_em are applied to the gates of the NMOS transistors 31 connected to the variable impedance circuits 13 and 14, respectively, to control the switching of the MOS transistors 31. The current source 30 flows the constant current Is of the current source 10 multiplied by α (coefficient), that is, a constant current α×Is.

An operation of the current output buffer circuit shown in FIG. 3 will be described below. At a rising time of the transmission signal inputs inp and inn, or in the period in which the bit rate of the transmission signal inputs inp and inn is high, the PMOS transistor 15 in the variable impedance circuit 13 or 14 is turned off so that the selection resistance element Roem connected to the turned-off PMOS transistor 15 is disconnected from the parallel connection with the corresponding resistance element Ro. At this time, the NMOS transistor 31 connected in series to the variable impedance circuit 13 or 14 in which the PMOS transistor 15 is turned off is controlled to be turned on, and hence, as viewed from the output node (signal transmission line side), the control resistance element Roem connected to the turned-on NMOS transistor 31 is connected in parallel with the resistance element Ro of the variable impedance circuit 13 or 14 in which the PMOS transistor 15 is turned off. Accordingly, it is possible to match the output impedance to the impedance Zo of the signal transmission line even at the rising time of the transmission signal inputs inp and inn, or even when the bit rate of the transmission signal inputs inp and inn is high. In other words, it is possible to match the output impedance to the impedance Zo of the signal transmission line, irrespective of the bit rate of the transmission signal.

Incidentally, in the current output buffer circuit shown in FIG. 3, although an extra current α×Is flows through the added control resistance element Roem. However, it is possible to increase the signal amplitude 2.5 times the original amplitude with the current increased by only 25% from that in the current output buffer circuit shown in FIG. 1, by setting Roem=Ro=2×Zo, and setting α=¼. By the method in which the current is simply increased to realize emphasis, an increase of the current up to 250% is required to obtain a signal amplitude 2.5 times the original amplitude. On the contrary, according to this embodiment, the desired emphasizing effect can be obtained by an increase in the current amount of 1/10 thereof.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit comprising:
a current output buffer circuit including a differential circuit, a variable impedance circuit, and a constant current source, wherein
the current output buffer circuit is driven by a constant current supplied by the constant current source, an output impedance of the current output buffer circuit is controlled in accordance with a bit rate of differential transmission signal inputs inputted to the differential circuit so that a waveform of a signal output from the current output buffer circuit to a signal transmission line is controlled in accordance with the bit rate of the transmission signal inputs.

2. The semiconductor integrated circuit according to claim 1, wherein the variable impedance circuit includes two or more parallel resistance elements controlled by a control signal so that a combined resistance of the resistance elements is set to be equal to an impedance of the signal transmission line or to an output impedance of an arbitrary value.

3. The semiconductor integrated circuit according to claim 2, wherein the parallel resistance elements of the variable impedance circuit are controlled so that the output impedance is increased when the bit rate of the transmission signal input is high.

4. The semiconductor integrated circuit according to claim 3, wherein the current output buffer circuit further includes a control resistance element connected to the parallel resistance elements of the variable impedance circuit, and a resistance of the control resistance element is controlled in accordance with the bit rate of the transmission signal input so that the output impedance matches to an impedance of the signal transmission line even when the bit rate of the transmission signal input is high.

5. The semiconductor integrated circuit according to claim 2, wherein the parallel resistance elements of the variable impedance circuit are controlled so that the output impedance of the current output buffer circuit is lowered when the bit rate of the transmission signal input is low.

6. A semiconductor integrated circuit comprising:
an input terminal which receives a transmission signal input;
an output terminal; and
a current output buffer circuit connected between the input terminal and the output terminal and driven by a constant current source, in which an output impedance of the current output buffer circuit is controlled in accordance with a bit rate of a transmission signal input inputted to the input terminal so that a waveform of a signal output from the current output buffer circuit to a signal transmission line is controlled in accordance with the bit rate of the transmission signal input.

7. The semiconductor integrated circuit according to claim 6, wherein the current output buffer circuit comprises a variable impedance circuit including two or more parallel resistance elements controlled by a control signal so that a combined resistance of the resistance elements is set to be equal to an impedance of the signal transmission line or to an output impedance of an arbitrary value.

8. The semiconductor integrated circuit according to claim 7, wherein the parallel resistance elements of the variable impedance circuit are controlled so that the output impedance is increased when the bit rate of the transmission signal input is high.

9. The semiconductor integrated circuit according to claim 8, further comprising a control resistance element connected to the parallel resistance elements of the variable impedance circuit, and a resistance of the control resistance element is controlled in accordance with the bit rate of the transmission signal input so that the output impedance matches to an impedance of the signal transmission line even when the bit rate of the transmission signal input is high.

10. The semiconductor integrated circuit according to claim 7, wherein the parallel resistance elements of the variable impedance circuit are controlled so that the output impedance of the current output buffer circuit is lowered when the bit rate of the transmission signal input is low.

11. A current output buffer circuit comprising:
a differential circuit which includes a pair of differential transistors,
an impedance circuit which includes a pair of variable resistance circuits connected in series to the pair of differential transistors, respectively, and
a constant current source which is connected between a node of the pair of differential transistors and the pair of variable resistance circuits and a reference potential terminal and supplies a constant current flowing through the pair of variable resistance circuits and the pair of differential transistors.

12. The current output buffer circuit according to claim 11, wherein the pair of variable resistance circuits of the impedance circuit comprise a pair of parallel resistance circuits connected in series to the pair of differential transistors of the differential circuit, respectively.

13. The current output buffer circuit according to claim 12, wherein each of the pair of parallel resistance circuits of the impedance circuit comprise two or more resistance elements connected in parallel to each other, and at least one of the two or more resistance elements of each of the parallel resistance circuits has a selection transistor connected in series to the one resistance element.

14. The current output buffer circuit according to claim 13, wherein a combined resistance of each of the pair of parallel resistance circuits when the selection transistor is turned on is equal to an impedance of a signal transmission line.

15. The current output buffer circuit according to claim 13, wherein a combined resistance of each of the pair of parallel resistance circuits when the selection transistor is turned off is larger than an impedance of a signal transmission line.

16. The current output buffer circuit according to claim 13, wherein the pair of differential transistors are of the same channel type to each other, the selection transistors are of the same channel type to each other, and the pair of differential transistors and the selection transistors are of different channel types from each other.

17. The current output buffer circuit according to claim 13, wherein the pair of differential transistors are controlled by complementary transmission signals, respectively, so that when one of the pair of differential transistors is turned on, the other of the pair of differential transistors is turned off, and the pair of selection transistors are controlled by complementary control signals synchorized with the complementary transmission signals, respectively, so that when one of the pair of selection transistors is turned on, the other of the pair of selection transistors is turned off.

18. The current output buffer circuit according to claim 13, wherein when one and the other of the pair of differential transistors are turned on and off, respectively, one and the other of the pair of selection transistors connected to the one and the other differential transistors, respectively, are turned off and on, respectively.

19. The current output buffer circuit according to claim 13, further comprising:
a pair of control resistance elements connected to nodes of the pair of variable resistance circuits and the pair of differential transistors, respectively, a resistance of each of the control resistance elements being equal to that of the at least one resistance element of the parallel resistance circuits;
a pair of control transistors of the same channel type to each other connected in series to the pair of control resistance elements, respectively, the pair of control transistors being of the same channel type to each other and of different channel type from a pair of the selection transistors in the variable resistance circuits; and
a constant current source connected between a node of the pair of control transistors and the pair of control resistance elements and the reference potential terminal and configured to supply a constant current flowing through the pair of control resistance elements and the pair of control transistors.

20. The current output buffer circuit according to claim 19, wherein the pair of control transistors are controlled by the complementary control signals supplied to the pair of the selection transistors, respectively, so that when one of the pair of control transistors is turned on, the other of the pair of control transistors is turned off, and when one and the other of the pair of selection transistors are turned on and off, respectively, one and the other of the control transistors corresponding to the one and the other of the pair of the selection transistors are turned off and on, respectively.
